(19) United States
(12) Patent Application Publication
(10) Pub. No.: US 2020/0051798 A1
(43) Pub. Date: Feb. 13, 2020

(54) COLLIMATOR FOR SELECTIVE PVD WITHOUT SCANNING

(71) Applicant: APPLIED MATERIALS, INC., Santa Clara, CA (US)

(72) Inventors: BENCHERKI MEBARKI, SANTA CLARA, CA (US); JOUNG JOO LEE, SAN JOSE, CA (US); XIANMIN TANG, SAN JOSE, CA (US)

(21) Appl. No.: 16/515,785

(22) Filed: Jul. 18, 2019

Related U.S. Application Data
(60) Provisional application No. 62/717,927, filed on Aug. 13, 2018.

(51) Int. Cl. H01J 37/34

(52) U.S. Cl. CPC H01J 37/3447; H01J 37/3405

(57) ABSTRACT

Collimator assemblies and process chambers for processing substrates including collimator assemblies are provided herein. In some embodiments, a collimator assembly may include a first cylindrical divider, a second cylindrical divider nested entirely within the first cylindrical divider, and a third cylindrical divider nested entirely within the second cylindrical divider, wherein an aspect ratio between a height of the cylindrical dividers and a width between two adjacent cylindrical dividers is maintained constant. In some embodiments, a process chamber for processing substrates may include a magnetron source, a target supported by a target backing plate cathode disposed below the magnetron source, and a collimator assembly having a plurality of nested cylindrical dividers, wherein an aspect ratio between a height of the cylindrical dividers and a width between two adjacent cylindrical dividers is maintained constant.

### CROSS-REFERENCE

This application claims benefit of U.S. Provisional Patent Application Ser. No. 62/717,927, filed Aug. 13, 2018 which is herein incorporated by reference in its entirety.

### FIELD

Embodiments of the present invention generally relate to substrate processing equipment and techniques, and more particularly, to methods and apparatus for depositing materials via physical vapor deposition.

### BACKGROUND

The semiconductor processing industry generally continues to strive for increased uniformity of layers deposited on substrates. For example, with shrinking circuit sizes leading to higher integration of circuits per unit area of the substrate, increased uniformity is generally seen as desired, or required in some applications, in order to maintain satisfactory yields and reduce the cost of fabrication. Various technologies have been developed to deposit layers on substrates in a cost-effective and uniform manner, such as chemical vapor deposition (CVD) or physical vapor deposition (PVD).

However, the inventors have observed that with the drive to produce equipment to deposit more uniformly, certain applications may not be adequately served where purposeful deposition is required that is not symmetric or uniform with respect to the given structures being fabricated on a substrate.

One technique developed to allow the use of PVD or CVD to deposit symmetric or asymmetric thin films on structures formed on a substrate is collimator sputtering. A collimator is a filtering plate positioned between a sputtering source and a substrate. The collimator typically has a uniform thickness and includes a number of passages formed through the thickness. Sputtered material must pass through the collimator on its path from the sputtering source to the substrate. The collimator filters out material that would otherwise strike the workpiece at acute angles exceeding a desired angle.

The actual amount of filtering accomplished by a given collimator depends on the aspect ratio of the passages through the collimator. As such, particles traveling on a path approaching normal to the substrate pass through the collimator and are deposited on the substrate. This allows improved coverage in the bottom of high aspect ratio features.

However, certain problems exist with the use of prior art collimators in conjunction with multi-zone magnetrons. Thicker layers of source material may be deposited in one region of the substrate than in other regions of the substrate. For example, thicker layers may be deposited near the center or the edge of the substrate, depending on the radial positioning of the small magnet. The distribution of material on the substrate may be M-shaped. This phenomenon not only leads to non-uniform deposition across the substrate, but it also leads to non-uniform deposition across high aspect ratio feature sidewalls in certain regions of the substrate as well.

In addition, existing collimators used with multi-zone magnetrons block half of the sputtered material due to space constraints and aspect ratio requirements of the collimator. Furthermore, scanning of the substrate is typically required for provide uniform deposition on the substrate and the structures formed on the substrate. However, scanning of the substrate reduces the efficiency and deposition rates of the material being deposited.

Therefore, a need exists for improvements in the uniformity of depositing source materials across a substrate by PVD and CVD techniques without scanning the substrate.

### SUMMARY

Collimator assemblies and process chambers for processing substrates including collimator assemblies are provided herein. In some embodiments, a collimator assembly may include a first cylindrical divider, a second cylindrical divider nested entirely within the first cylindrical divider, and a third cylindrical divider nested entirely within the second cylindrical divider, wherein an aspect ratio between a height of the cylindrical dividers and a width between two adjacent cylindrical dividers is maintained constant.

In some embodiments, a process chamber for processing substrates may include a magnetron source, a target supported by a target backing plate cathode disposed below the magnetron source, and a collimator assembly having a plurality of nested cylindrical dividers, wherein an aspect ratio between a height of the cylindrical dividers and a width between two adjacent cylindrical dividers is maintained constant, and wherein the plurality of nested cylindrical dividers are not concentric and do not have the same central axis.

In some embodiments, a collimator assembly may include a plurality of nested cylindrical dividers, wherein an aspect ratio between a height of the cylindrical dividers and a width between two adjacent cylindrical dividers is maintained constant, and wherein the plurality of nested cylindrical dividers are not concentric and do not have the same central axis, and support features to maintain a fixed width between the nested cylindrical dividers.

Other and further embodiments of the present invention are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1A depicts a schematic diagram of an apparatus used for PVD deposition of material on substrates in accordance with some embodiments of the present disclosure.

FIG. 1B depicts a breakout isometric view of the collimator assembly of FIG. 1A in accordance with some embodiments of the present disclosure.

FIG. 2 depicts a schematic diagram of the collimator assembly including the heights and widths of the divider blades in accordance with some embodiments of the present disclosure.

FIG. 3 depicts a schematic diagram of the collimator assembly in accordance with some embodiments of the present disclosure.

FIG. 4 depicts a schematic top down view of the collimator assembly in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The inventors have provided methods and apparatus for depositing materials via PVD or CVD of materials at an angle to the substrate (as compared to about 90 degrees to the surface of the substrate). For example, material to be deposited may be provided in a stream of material flux from a PVD source that is provided at a non-normal angle to the substrate. The inventors have further observed that embodiments of the inventive multi-zone collimator assembly described herein having a plurality of nested cylindrical dividers, as opposed the used of single-zone collimation, advantageously enhances efficient use of dual-lobe linear magnetron sources, enhances deposition rates and throughputs, and lowers cost and defects per substrate processed. The inventive collimator assembly described herein advantageously controls thickness uniformity by the collimator aspect ratio of each cylindrical divider, and advantageously filters/controls the deposition spread angle by the collimator assembly divider blades.

Typically, however, the substrate is scanned, or moved through the stream of material flux to deposit a layer of material on the substrate when collimators are used. In those instances, the substrate may be scanned multiple times to deposit material to a final thickness. However, scanning of the substrate reduces the efficiency and deposition rates of the material being deposited. Specifically, because the magnets in the magnetrons in the chambers are linear and have a linear origin, the use of standard collimators reduces the efficiency and deposition rate of the material being deposited. Furthermore, some chambers that would benefit from the use of a collimator do not have scanning capabilities and cannot move the substrate laterally through the stream of material flux. Embodiments of the collimator described herein advantageously can be fit into chambers that don't have scanning capabilities while improving the efficiency, deposition rate and uniformity of the material being deposited.

Embodiments of the disclosed methods and apparatus can be used for fin selective doping and oxidation, selective spacer for a silicon fin, selective sidewall contact (e.g. Ti on Si), asymmetric deposition for tighter end-to-end spacing without extreme ultraviolet (EUV) lithography masks, asymmetric fin stressor for channel mobility, selective etch hard masks, Si fin protection layer, selective barrier deposition for low via R metallization with overhang control, spacer deposition for SAXP, line edge roughness control for etch hard mask, pattern CD, and profile modulation.

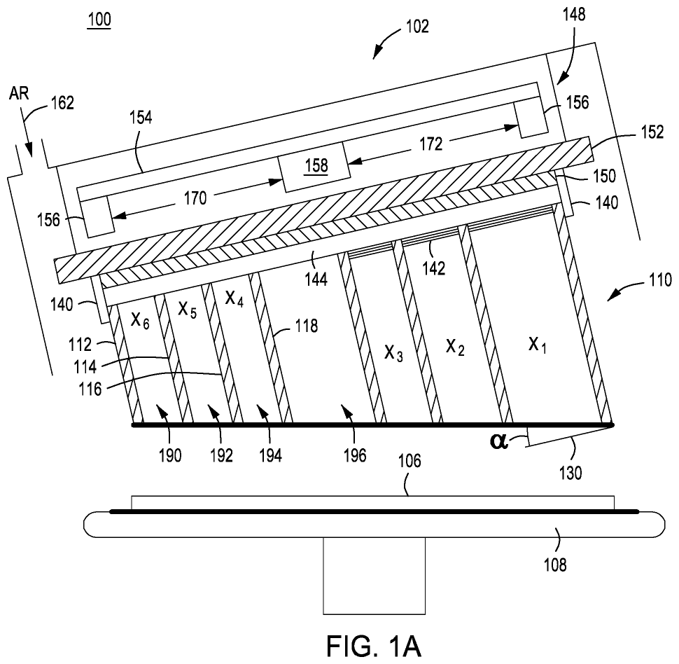

FIG. 1 depicts a schematic diagram of an apparatus used for PVD deposition of material on substrates in accordance with some embodiments of the present disclosure. Specifically, FIG. 1 schematically depicts an apparatus 100 for PVD of materials on a substrate at an angle to the generally planar surface of the substrate. The apparatus 100 generally includes a first PVD source 102, a substrate support 108 for supporting a substrate 106, and a collimator assembly 110. The first PVD source 102 is configured to provide a stream of material flux (from the source toward the substrate support 108 and any substrate 106 disposed on the substrate support 108. The substrate support has a support surface to support the substrate such that a working surface of the substrate to be deposited on is exposed to the stream of material flux.

The first PVD source 102 includes target 150 with target material to be sputter deposited on the substrate. In some embodiments, the target material can be, for example, a metal, such as titanium, or the like, suitable for depositing titanium (Ti) or titanium nitride (TiN) on the substrate. In some embodiments, the target material can be, for example, silicon, or a silicon-containing compound, suitable for depositing silicon (Si), silicon nitride (SiN), silicon oxynitride (SiON), or the like on the substrate. Other materials may suitably be used as well in accordance with the teachings provided herein. The linear PVD source 102 further includes, or is coupled to, a power source to provide suitable power for forming a plasma proximate the target material and for sputtering atoms off of the target material. The power source can be either or both of a DC or an RF power source.

In some embodiments, unlike an ion beam or other ion source, the first PVD source 102 is configured to provide mostly neutrals and few ions of the target material. As such, a plasma may be formed having a sufficiently low density to avoid ionizing too many of the sputtered atoms of target material. For example, for a 300 mm diameter wafer as the substrate, about 1 to about 20 kW of DC or RF power may be provided. The power or power density applied can be scaled for other size substrates. In addition, other parameters may be controlled to assist in providing mostly neutrals in the stream of material flux. For example, the pressure may be controlled to be sufficiently low so that the mean free path is longer than the general dimensions of an opening of the first PVD source 102 through which the stream of material flux passes toward the substrate support 108 (as discussed in more detail below). In some embodiments, the pressure may be controlled to be about 0.5 to about 5 millitorr.

In embodiments consistent with the present disclosure, the lateral angles of incidence of the first and second streams of material flux can be controlled. For example, FIG. 1A depicts apparatus 100 illustrating material deposition angle (a) 130 of the stream from the first PVD source 102 in accordance with at least some embodiments of the present disclosure.

In some embodiments, the PVD source 102 includes a single zone magnetron assembly. In other embodiments, the PVD source 102 includes a multi-zone magnetron assembly 148 that creates two or more zones (e.g., a first zone 170 and a second zone 172) of magnetic fields lines for sputtering target material from the target 150. In some embodiments, the magnetron assembly 148 includes at least one target 150, a target backing plate cathode 152, and a yoke 154 that is used to support a plurality of outer magnets 156 and inner magnets 158. The plurality of outer magnets 156 and inner magnets 158 create a plurality of magnetic tracks. The magnetic fields generated by the interaction of the inner magnets 158 and the outer magnets 156 create the plurality of magnetic zones for sputtering materials from target 150 when the plasma is generated. The cathode 152 and target 150 are biased to a negative DC bias in the range of about −100 to −600 VDC to attract positive ions of the working gas 162 (e.g., argon) toward the target to sputter the metal atoms. The induced magnetic field from the pair of opposing magnets (e.g., magnets 156, 158) trap electrons and extend the electron lifetime before they are lost to an anodic surface or recombine with gas atoms in the plasma. Due to the extended lifetime, and the need to maintain charge neutrality in the plasma, additional argon ions are attracted into the region adjacent to the magnetron to form there a high-density plasma. Thereby, the sputtering rate is increased. However, the atoms and molecules of sputtered material directed towards the substrate surface come from various angles, and only a comparatively small portion are incident substantially perpendicular to the substrate surface. As a result, it is difficult for sputtering to achieve desired coverage within high aspect ratio steps or contacts (e.g., features) on semiconductor wafer substrate, or to achieve asymmetric deposition of material on the features.

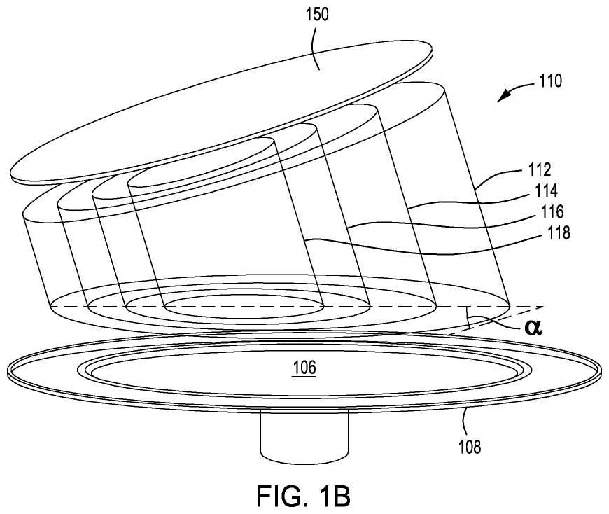

To overcome this drawback, a device known as a collimator is used. In some embodiments, the inventive collimator assembly 110 is a physical structure such as plurality of nested cylindrical dividers that form a plurality of openings 190, 192, 194, 196 that is interposed between the PVD source 102 and the substrate 106 such that the stream of material flux travels through the structure (e.g., collimator assembly 110). The collimator assembly 110 may include a plurality nested cylindrical dividers. FIG. 1A depicts four nested cylindrical dividers 112, 114, 116 and 118 that form the plurality of openings 190, 192, 194, 196, although more or less dividers may be used. The walls of each of the nested cylindrical dividers 112, 114, 116 and 118 are referred to as dividers blades. Each cylindrical dividers 112, 114, 116 and 118 includes a short divider blade side (e.g., 118S in FIG. 2) and an opposing long divider blade side (e.g., 118L in FIG. 2). Any materials with an angle to great to pass through the openings 190, 192, 194, 196 of the collimator assembly 110 will be blocked, thus limiting the permitted angular range of materials reaching the surface of substrate 106. FIG. 1B depicts an isometric breakout view of the collimator assembly 110 to further illustrate the nested nature of the plurality of cylindrical dividers that make up the collimator assembly 110. The thickness of each of the nested cylindrical dividers 112, 114, 116 and 118 may be about 0.5 mm thick to about 5 mm thick. In some embodiments, the thickness of each of the nested cylindrical dividers 112, 114, 116 and 118 is about 2 mm thick. In some embodiments, the collimator assembly 110 may be supported under the target by one or more supports 140. In some embodiments, each of the nested cylindrical dividers may be separately supported to the target assembly/target backing plate or the chamber. In other embodiments, the nested cylindrical dividers are attached to each other via optional support features 142 to better control the widths between the divider blades, and ensure they do not move with respect to each other. In some embodiments, there is gap 144 maintained between the top of the collimator assembly 110 and the bottom of the target 150 where the plasma forms. In some embodiments, the unobstructed gap may be about 1 cm to about 20 cm.

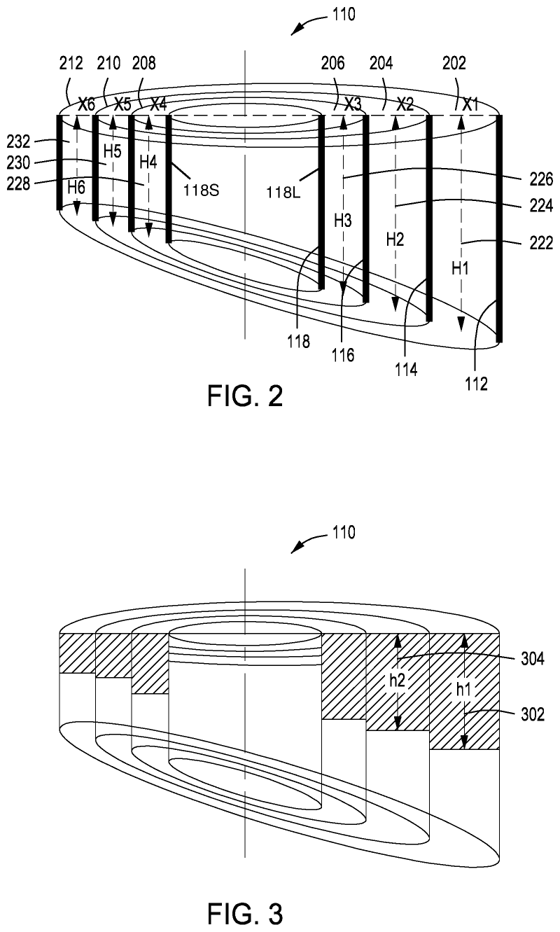

Thus, the collimator assembly 110 functions effectively as a filter, allowing only the atoms and molecules incident perpendicular to the target 150 to pass through and coat the substrate 106, thereby controlling the spread angle of the stream of material flux. However, the widths of the openings (e.g., 190, 192, 194, 196) of collimators are limited by space limitation within the chamber and aspect ratio constraints. That is, referring to FIGS. 2 and 3, the widths X1 (202), X2 (204), X3 (206), X4 (208), X5 (210) and X6 (212) between divider blades of dividers 112, 114, 116, 118 of the collimator assembly 110 must be within a certain width with respect to the corresponding heights H1 (222), H2 (224), H3 (226), H4 (228), H5 (230), H6 (232) of the collimator assembly 110 for deposition material scatter reduction. In some embodiments, the heights H1 (222), H2 (224), H3 (226), H4 (228), H5 (230), H6 (232) may be measured from a top opening of the collimator assembly 110 opening to a bottom opening of the collimator assembly 110. In some embodiments, the heights H1 (222), H2 (224), H3 (226), H4 (228), H5 (230), H6 (232) may be measured along an approximately central point between two collimator blades. In some embodiments, the heights H1 (222), H2 (224), H3 (226), H4 (228), H5 (230), H6 (232) may be measured along an approximately central point between two long divider blade sides and two short divider blade sides. In other embodiments, the heights H1 (222), H2 (224), H3 (226), H4 (228), H5 (230), H6 (232) may be measured along other sections of the collimator assembly or be an average height measurement.

Further compounding this size limitation is that a specified aspect ratio should be maintained. One skilled in the art will readily appreciate that “aspect ratio” is the dimensional ratio of the length or height of the divider blades in the y-direction relative to the width between the divider blades in the x-direction. As shown in FIG. 1, the heights 222, 224, 226, 228, 230, 232 of each divider blade for each cylindrical divider in collimator assembly 110 is different, with some divider blades extending closer to the substrate than others. That ratio for maintaining a balanced deposition ratio is:

$$\frac{{H}_{1}}{{x}_{1}} = \frac{{H}_{2}}{{x}_{2}} = … = \frac{{H}_{i}}{{X}_{i}}$$

The above ratio is the collimator aspect ratio that needs to be maintained to assure a constant deposition rate over the entire substrate 106. Thus, thickness uniformity can be controlled by the collimator aspect ratio. Meanwhile the condition for spread angle control using the nested cylindrical dividers should adhere to the following ratio:

$$h 1 = \frac{{H}_{1}}{2} ; … hi = \frac{{H}_{i}}{2}$$

FIG. 3 depicts examples of the heights h1 (302), and h2 (304) used to determine spread angle control.

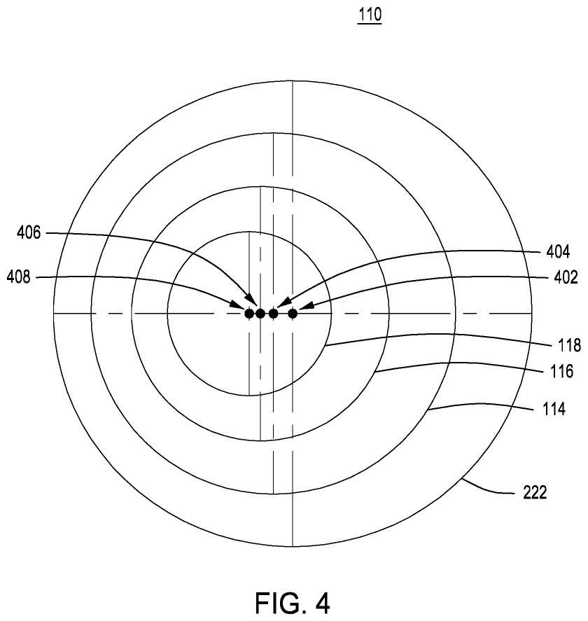

FIG. 4 depicts a schematic top down view of the collimator assembly 110 in accordance with some embodiments of the present disclosure. As shown in FIG. 4, the centers of each of the nested cylindrical dividers are shifted. That is, the nested cylindrical dividers are not concentric sharing the same central axis. As shown in FIG. 4, the central axis (i.e., center) of nested cylindrical divider 112 is 402, the central axis (i.e., center) of nested cylindrical divider 114 is 404, the central axis (i.e., center) of nested cylindrical divider 116 is 406, and the central axis (i.e., center) of nested cylindrical divider 118 is 408.

While the foregoing is directed to embodiments of the present disclosure, other and further embodiments of the disclosure may be devised without departing from the basic scope thereof.

1. A collimator assembly, comprising:
a first cylindrical divider; and
a second cylindrical divider nested within the first cylindrical divider; and
a third cylindrical divider nested within the second cylindrical divider,
wherein an aspect ratio between a height of the cylindrical dividers and a width between two adjacent cylindrical dividers is maintained constant.

2. The collimator assembly of claim 1, wherein the first, second and third cylindrical dividers are not concentric and do not have the same central axis.

3. The collimator assembly of claim 1, wherein each of the first, second and third cylindrical dividers has a first open end and an opposing second open end, and wherein the second open end is angled with respect to the first open end such that a height of a wall of each cylindrical divider varies about its diameter.

4. The collimator assembly of claim 1, wherein each of the first, second and third cylindrical dividers include a top opening and a bottom opening.

5. The collimator assembly of claim 1, wherein the collimator assembly includes a plurality of openings formed between each of the nested first, second and third cylindrical dividers.

6. The collimator assembly of claim 5, wherein the plurality of openings formed between each of the nested first, second and third cylindrical dividers extends from a top opening of the collimator assembly to a bottom opening of the collimator assembly.

7. The collimator assembly of claim 1, wherein the height used to determine the aspect ratio is measured along a point between two divider blade.

8. The collimator assembly of claim 1, wherein each of the nested first, second and third cylindrical dividers includes a short divider blade side and an opposing long divider blade side.

9. The collimator assembly of claim 8, wherein the height used to determine the aspect ratio is measured along a point between two long divider blade sides and two short divider blade sides.

10. The collimator assembly of claim 1, wherein the nested cylindrical dividers are attached to each other via support features to maintain a fixed width between the nested cylindrical dividers.

11. A process chamber for processing substrates, comprising:
a magnetron source;
a target supported by a target backing plate cathode disposed below the magnetron source; and
a collimator assembly having a plurality of nested cylindrical dividers, wherein an aspect ratio between a height of the cylindrical dividers and a width between two adjacent cylindrical dividers is maintained constant, and wherein the plurality of nested cylindrical dividers are not concentric and do not have the same central axis.

12. The process chamber of claim 11, wherein the collimator assembly is supported under the target by one or more supports.

13. The process chamber of claim 11, wherein each of the nested cylindrical dividers are separately supported to the target backing plate or the chamber.

14. The process chamber of claim 11, wherein the nested cylindrical dividers are attached to each other via support features to maintain a fixed width between the nested cylindrical dividers.

15. The process chamber of claim 11, wherein a gap is maintained between the top of the collimator assembly and the bottom of the target where a plasma can form.

16. The process chamber of claim 15, wherein the gap is about 1 cm to about 20 cm.

17. The process chamber of claim 11, wherein the collimator assembly is configured to filter atoms and molecules discharged from the target that are not perpendicular to the target.

18. The process chamber of claim 11, wherein the collimator assembly is configured to control a spread angle of a stream of material flux discharged from the target.

19. A collimator assembly, comprising:
a plurality of nested cylindrical dividers, wherein an aspect ratio between a height of the cylindrical dividers and a width between two adjacent cylindrical dividers is maintained constant, and wherein the plurality of nested cylindrical dividers are not concentric and do not have the same central axis; and
support features to maintain a fixed width between the nested cylindrical dividers.

20. The collimator assembly of claim 19, wherein each of the plurality of nested cylindrical dividers has a first open end and an opposing second open end, and wherein the second open end is angled with respect to the first open end such that a height of a wall of each cylindrical divider varies about its diameter.
